(19) United States
(12) Patent Application Publication
(10) Pub. No.: US 2011/0139756 A1
(43) Pub. Date: Jun. 16, 2011

(54) DEVICE FOR STRUCTURING A SOLAR MODULE

(75) Inventors: Adrian Raible, Veyrier (CH); Richard Bartlome, Prangins (CH); Yann Sinquin, Neuchatel (CH)

(73) Assignee: ATEC HOLDING AG, LANGENTHAL (CH)

(21) Appl. No.: 13/000,422

(22) PCT Filed: Jun. 15, 2009
(86) PCT No.: PCT/CH09/00203

§ 371 Date: Feb. 25, 2011

(30) Foreign Application Priority Data
Jun. 25, 2008 (EP) 08405163.0

(51) Int. Cl. H01L 31/18; B23K 26/08; B23K 26/36; B25B 11/00

(52) U.S. Cl. 219/121.68; 219/121.76; 219/121.78; 269/21

(57) ABSTRACT

A device for structuring a solar module. A retainer device arranged above the solar modules to be machined comprises retainer means which retain the solar modules. The retention is achieved in a non-contact manner. In a region beneath the solar module a structuring tool is arranged mounted to be mobile in a longitudinal and a transverse direction. The structuring tool can thus machine the complete surface of the solar module.

### CROSS-REFERENCE TO RELATED APPLICATIONS

This application is a National Stage Application of PCT/CH2009/000203, filed Jun. 15, 2009, which designates the United States and claims the priority of European Patent Application No. 08405163, filed on Jun. 25, 2008.

### BACKGROUND

1. Field of the Invention

The invention relates to a device for structuring a solar module.

2. Related Art

Solar modules in solar energy systems comprise substantially flat glass plates, which are coated on one side. The coating usually consists of multiple layers overlaid on one another, of which at least one layer is electrically conducting. For technical reasons relating to production the glass module is fitted contiguously with the coating. In order to generate an acceptably high electrical current the applied coating must be divided into individual sections. As well as a purely mechanical structuring of the surface using appropriate tools, an optical structuring of these solar modules has also established itself.

In the optical structuring the coating is produced by means of a laser, which burns thin to very thin discontinuities into the coating with a certain degree of precision.

A system for structuring solar modules is known from DE 10 2006 033 296 A1. This structuring system comprises a transport system with which a glass module can be transported within the system. For transporting and retaining the solar module the transport system is equipped with a plurality of air nozzles, by means of which the solar module floats on an air bearing. The coating is located on the upper side of the solar module remote from the transport system. A structuring tool, namely a laser, is arranged underneath the transport system and the glass plate to be structured. The laser is displaceable perpendicular to a transport direction of the solar module.

In order to structure the coating, the focus of the laser is directed on to the region of the coating, wherein a laser beam passes through the glass plate of the solar module. In the focussing range of the laser the coating is vaporised, which allows the desired discontinuity to be produced.

To achieve a structuring in the longitudinal direction of the solar module, which corresponds to a transport direction of the module, the module must be displaced over a working range of the laser. On account of the air nozzles arranged underneath the glass plate, the working range corresponds to only a small gap extending perpendicular to the transport direction. To perform the structuring the glass is displaced over this working range, this procedure being repeated as often as necessary until the structuring of the solar module has been completed.

Above the working range a suction device is arranged, which sucks particles or waste gases resulting from the structuring process away from the surface of the solar module, which could otherwise remain in place and possibly adversely affect a repeated structuring displacement of the laser even if only in a neighbouring region.

On account of the transport system, which is arranged underneath the solar module, the mobility of the laser is considerably restricted. The latter is, as explained above, only moveable perpendicular to the transport direction of the solar module. To structure the module it must be moved over the laser again and again. The glass plate therefore may be moved only with extreme care, as due to the thickness of the glass the glass plate can easily be broken. In particular a high acceleration represents a loading on the glass plate that is to be avoided. This results in a relatively slow machining of the solar module with the laser.

In addition to the relatively restricted mobility of the laser, limiting of the accuracies of the focussing range and of the individual tracks is found. In particular, with the arrangement of the laser and the movement of the glass the structuring cannot be adjusted later, which adversely affects the accuracy and therefore the quality of the solar modules.

### SUMMARY

A problem addressed by the invention is to improve a device of the type mentioned initially, by means of faster machining times and a higher machining quality.

A device for solving the problem according to the invention is provided. The solar module is retained on an upper side facing away from the structuring tool. The solar module is introduced into the device with a coated upper side facing upwards, where it is retained by a retaining device arranged on this same side. An underside of the solar module therefore remains free, wherein the possible risks of damage to the coating due to the retaining device are minimised. Thus, any falling objects, for example, are not left lying on the retaining device. The upper side of the solar module is not guided past stationary objects, which could be the cause of damage.

According to an embodiment of the invention, retention of the solar module is achieved in a non-contact manner. Due to the non-contacting retention, the risk of damaging the solar module is minimised. Glass that is thin and of fairly low quality is preferably used to manufacture a solar module. This glass however is not only lower in cost than high-quality plate glasses, but also more fragile to handle. A non-contact method of handling the solar module can therefore contribute to reducing damage caused, or even protecting against glass breakage.

In another embodiment of the invention, the retaining device comprises at least one, preferably a plurality of, retainer means. These retainer means are distributed evenly over the upper side of the solar module. The even distribution reduces deformations in the glass, and therefore contributes to a more accurate structuring and prevention of damage. To achieve a non-contacting retention, a negative pressure is generated on the upper side of the solar module by the retainer means by means of compressed air. The retainer means holds the module by suction due to compressed air blown out radially on to the top of the solar module, which is referred to as the Bernoulli principle. Between the retainer means, also known as a Bernoulli gripper, and the solar module a small gap is formed by the escape of compressed air. The solar module therefore floats underneath the retaining device.

In a further embodiment of the retainer means, to achieve a non-contacting retention the retainer means sucks up the module by means of suction air. By means of compressed air an air cushion is formed at the same time. The solar module therefore, held by the suction air, floats underneath the retaining device.

The structuring tool is arranged so that it can freely move underneath the retaining device. Due to the elimination of a retaining device under the glass module, the space can therefore be used for the structuring tool. The retaining device with the retainer means holds the solar module immobile in one position, so that the structuring tool that moves underneath the solar module can apply the structure to the coating. In addition the service lifetime of the structuring device is also improved by the free space underneath the retaining device. In the event of glass breakage, with the device according to the invention there is no need for costly cleaning of the transport system. Glass shards can be simply left in the free space and removed at a later date.

In another embodiment the structuring tool comprises at least one carriage and at least one laser, for example, a plurality of lasers. The lasers are moveable in a longitudinal and a transverse direction. The plurality of lasers enables a faster machining time for the solar module, since multiple discontinuities can be burnt into the coating by the lasers at the same time. The lasers are also insensitive to accelerations, under which the glass of the solar modules would break. This makes an additional acceleration in the structuring possible.

According to another embodiment the carriage has a bearer, on which lasers are arranged, and which can be displaced in the longitudinal direction on two parallel running guides. The lasers themselves are displaceable on the bearer in the transverse direction of the structuring tool. The lasers can thus be moved in two dimensions under the solar module to be machined. With the two-dimensionality moreover, it is possible to implement parallel or simultaneous movements in the longitudinal direction and the transverse direction of the solar module. The guides are arranged in the longitudinal direction of a glass module, so that the bearer can be displaced smoothly.

According to another embodiment, at each of its free ends the bearer comprises a chassis which mates with one of the guides. By means of the chassis the carriage is connected to the guides, which means an exact trajectory of the bearer is achieved. The bearer is arranged perpendicular to the longitudinal direction of the guides. The bearer itself also comprises a guide, in which the laser or lasers are arranged. Each of the lasers is accommodated in an approximately shoebox-sized box, wherein the boxes, as already mentioned, can withstand high accelerations, up to 10 g. The boxes with the lasers are preferably arranged immediately next to one another on the bearer and parallel over a longitudinal extension of the bearer. Primarily the lasers are displaced en bloc, but they can also be controlled individually, so that for example one or more lasers can be positioned in the region of the one end, one or more lasers at another end and again, one or more lasers in a central region of the bearer, in order to be arranged next to one another again from there.

According to another embodiment of the invention the guide is arranged in a plane with the solar module. By means of this arrangement possible movements of the laser have no effect on the accuracy of the focussing point of the laser on the upper side of the glass plate. The movements are referred to as “pitching”, “rolling” and “yawing” and determine a direction of rotation of three axes passing through the laser. It is also possible however to let the plane of the module correspond to a rotational axis or to a point of the chassis that serves to ensure accuracy.

In a further embodiment of the invention, an area of free space is left underneath a machining region of the structuring tool. With the arrangement of the retaining device above the solar module the device can be designed to be substantially smaller, but in particularly a construction carrying the retaining unit can also be formed by a compound table. The compound table facilitates a lighter construction for the client, since the ability of the device to be transported is simplified. The space is therefore free, so that there is room here for any glass plates or shards of broken glass plates that fall down. As already mentioned above, broken glass plates do not need to be removed immediately from the device, since they have no effect on any working process. Any cleaning required can take place at a later date. Alternatively a collecting pan can be provided, in which the shards can be caught.

According to another embodiment, the retaining device is freely rotatable by 90° parallel to a plane of the solar module. The structuring of the coating on the solar module can be very complex and comprise different shapes. To this end it is necessary to allow the laser beam to pass not only perpendicular to and along the glass plate, but also diagonally or at an angle to a side of the glass plate. By rotation of the retaining device and the glass plate retained thereon this structuring direction can be implemented with little effort.

The retaining device serves to remove by suction any layer particles vaporised and burned off by the laser. The laser heats up the coating of the solar module in the area of its focussing region, which means that the coating is heated up and burned off or vaporised. This causes dirt particles to form on the top of the solar module, which must be removed. According to an embodiment of the invention the retaining device is formed from a plurality of Bernoulli grippers, which apply compressed air to the top. The air escapes from the grippers to the side and therefore in a simple manner transports the dirt particles away from the solar module, which are captured by the air stream of one or more grippers. Waste gases arising from the combustion can also be removed to the side by the strong flow. To the side in a region of the edges or of the solar module or above it, a suction device is provided which draws off the waste gases and dirt particles.

According to another embodiment, a positioning aid is arranged to the side of the solar module, which lies at least partly in the plane of the solar module. The positioning aid enables the positioning and/or fixing of the solar module. By means of the touch-free or contact-free retention of the solar module using the retaining device, the solar module could be displaced laterally. To avoid lateral movements the positioning aid serves as a stop edge, with which the solar module is retained laterally. This results in the advantageous possibility of coating the entire upper side with a single coating and also of machining this using the laser.

### BRIEF DESCRIPTION OF THE DRAWINGS

An embodiment of the invention will now be discussed with the aid of the drawings. They show:

FIG. 1 a perspective side view of the device according to an embodiment of the invention from a first long side,

FIG. 2 a perspective side view of the device according to an embodiment of the invention from a second long side,

FIG. 3 a perspective view from underneath the device according to an embodiment of the invention,

FIG. 4 a top view on to the device according to an embodiment of the invention,

FIG. 5 a front view of the device according to an embodiment of the invention, and

FIG. 6 an extracted view of the structuring tool with retaining device.

### DETAILED DESCRIPTION

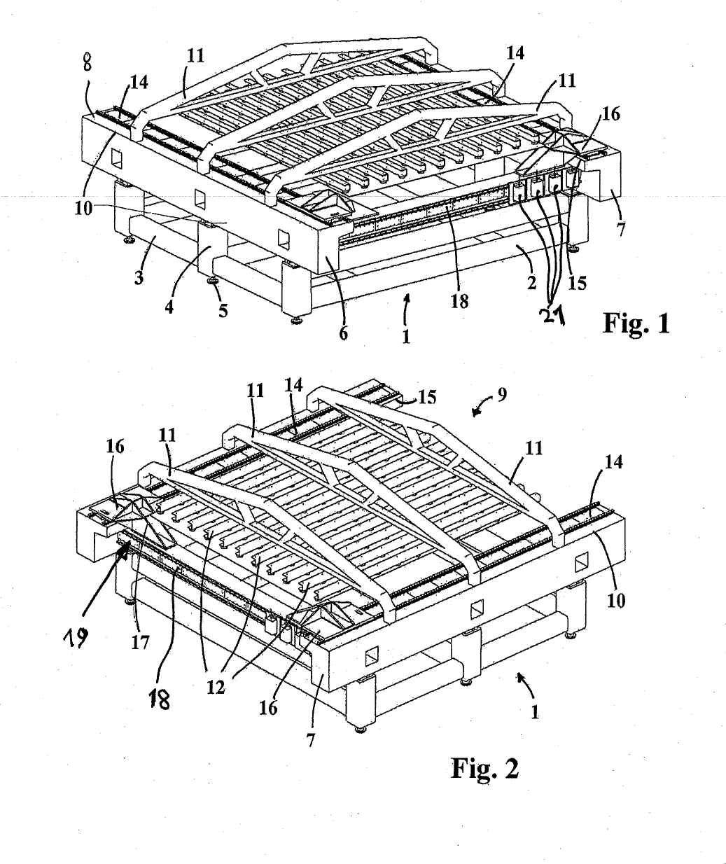

FIGS. 1 and 2 of the drawings show the device according to an embodiment of the invention in perspective view from a first and second long side. The device comprises a sub-frame 1, which is formed of transverse struts 2, longitudinal struts 3 and feet 4. The sub-frame 1 is formed in the manner of a compound table. On the undersides of the feet 4 adjustment devices 5 are arranged, with which unevennesses in the base underlying the device can be compensated for.

Lateral mounting elements 6, 7 are arranged on each of three feet 4 located on long sides of the sub-frames 1. On their top side the feet 4 form a horizontal plane, by means of which the mounting elements 6, 7 are mounted horizontally. By means of the adjustment devices 5 on the feet 4 final adjustments can be made for a horizontal mounting of the sub-frame 1. In addition, a connecting element is placed between each of the feet 4 and the mounting elements 6, 7 respectively. The connecting element serves to make a connection between a foot 4 and the mounting element 6, 7. The respective connecting element also comprises an adjustment facility, with which the mounting elements 6 and 7 can additionally be brought into a horizontal position.

The mounting elements 6, 7 are of solid construction and have a low thermal expansion coefficient. The mounting element 6, 7 is constructed as an inverse L-bracket. The underside of the L forms the top of the mounting element 6, 7, wherein an inner side of the members of the mounting element 6, 7 positioned relative to one another points in the direction of the other mounting element 6, 7. The part of the mounting element 6, resting on the feet 4 is larger in its physical dimensions than the other member forming the upper side.

A retaining device 9 is positioned between the opposite lying mounting elements 6 and 7. Bearing elements 11 are positioned in the region of outward facing edges 10 of the mounting elements 6 and 7, which are rigidly connected to the mounting elements 6 and 7. The bearing elements 11 therefore extend over the entire width of the device. Altogether, three such bearing elements 11 are shown in the figures, which are arranged next to one another. In other embodiments of the device however it may be necessary to provide more or fewer bearing elements 11 than those shown. The bearing elements 11 are designed to accommodate large loads.

On an underside of the bearing elements 11, mutually parallel U-profiles 12 are arranged. The U-profiles 12 are attached to a member on the underside of the bearing elements 11. On another member, lying parallel to the member connected to the bearing element 11, retainer means 13 (see FIG. 6) are arranged. The retainer means 13 lie on an outer side of the U-profile 12 and point in the direction of sub-chassis 1. Each U-profile 12 comprises a plurality of retainer means 13. The retainer means 13 are distributed evenly on the underside of the bearing elements 11 with the U-profiles, wherein as small a grid of retainer elements 13 as possible is provided.

Also on the upper side 8 of the mounting elements 6 and 7 a guide 14 is arranged. The guide 14 is arranged in a region of an inner edge 15 of the mounting elements 6 and 7. The guides 14 extend exactly parallel to one another. Chassis 16 are guided in the respective guides 14 of the mounting elements 6 and 7. The chassis 16 extend at least in part above the guides 14 and are bounded from above by the bearing elements 11. In the region of the guides 14 the bearing elements 11 are spaced apart from them. The chassis 16 can therefore be guided through between the bearing elements 11 and the guide 14.

The chassis 16 is constructed to be broader than the guide 14 and projects beyond the inner edge 15. On the chassis 16 a retainer 17 is arranged at the side, which extends underneath the inwardly pointing member of the bearing element 6, 7. The retainer 17 also extends outside of the chassis 16, i.e. it rests on the chassis. To an underside of the respective retainers 17 a bearer 18 is attached, which extends between the retainers 17 and joins them together. The construction consisting of chassis 16, retainer 17 and bearer 18 forms a so-called carriage 19. The retainer 17 extends vertically from the chassis 16 to the bearer 18 along the inner edge 15. The bearer 18 itself extends laterally outwards over the respective retainers 17. The bearer 18 therefore lies at least partly underneath the upper side 8 and the guide 14. The bearer 18 is bounded to the side by the member of the mounting elements 6 and 7 connected to the feet 4.

The bearer 18 also comprises a guide, which in the exemplary embodiment according to the invention is in the form of a rail. The rail 20 extends over the entire length of the bearer 18. The rail 20 is attached to an outer side of the bearer 18, wherein it is connected to it on an outer side of the bearer 18.

A plurality of lasers 21 are arranged on the bearer 18. The lasers 21 are moveably connected to the rail 20. The lasers 21 are moveable laterally on the bearer 18 over the width of the device. The lasers are accommodated in respective boxes, which are individually connected to the rail 20. Therefore, the lasers 21 can be moved over the bearer 18 separately or as a unit. The lasers 21 are aligned in the direction of the retaining device 9. A laser beam from the respective lasers 21 thus extends in a vertical direction.

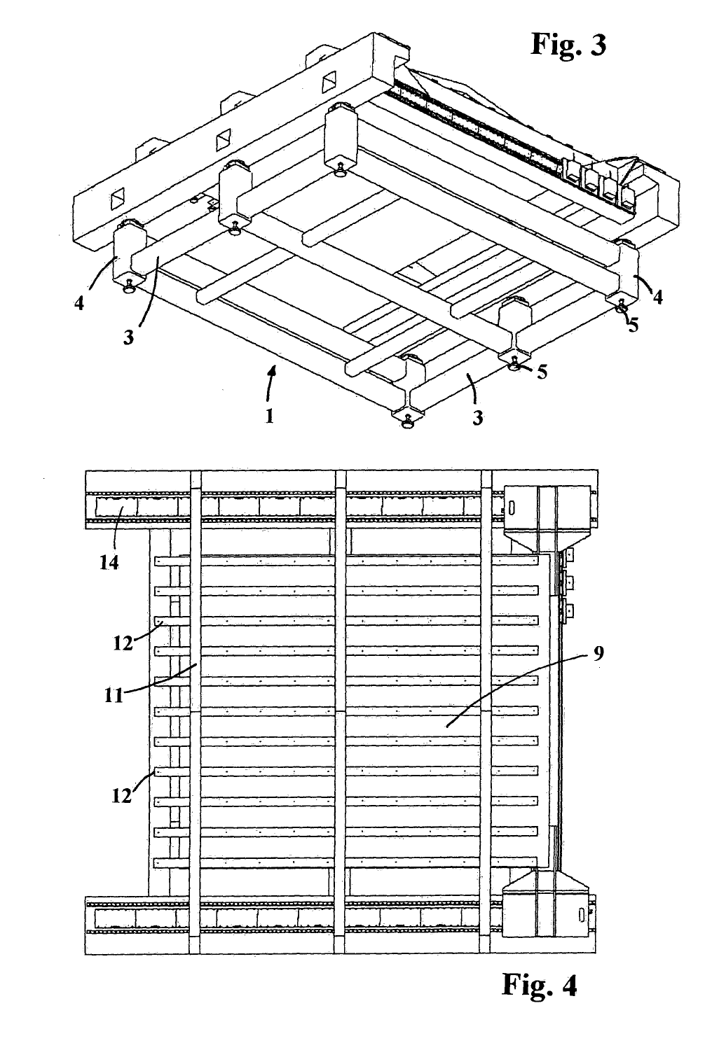

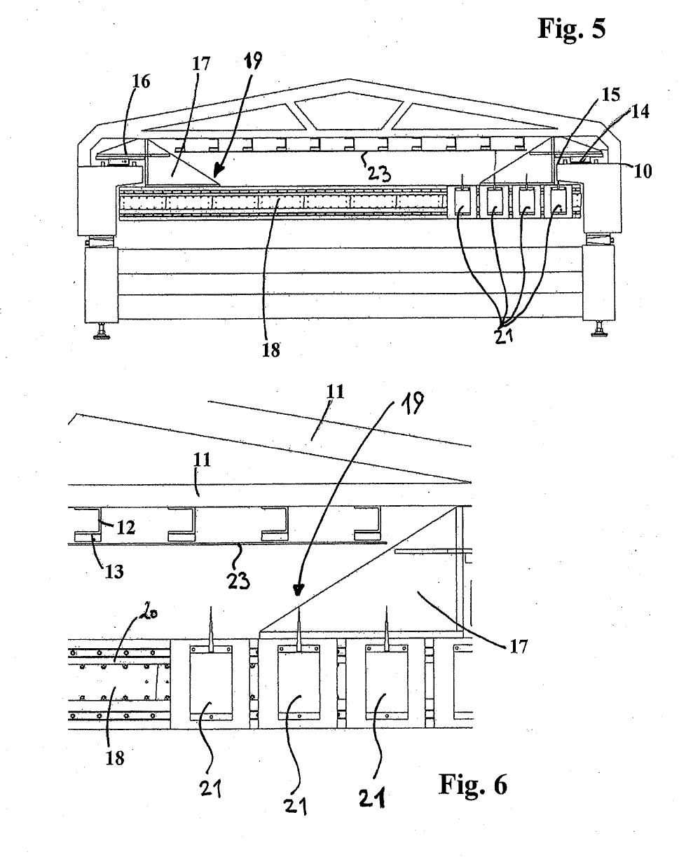

The carriage 19 with the lasers 21 attached to the bearer 18 is moveable in a longitudinal direction of the device, that is, along the mounting elements 6 and 7. At the same time the lasers 21 can be displaced perpendicularly to this motion. In the exemplary embodiment shown in FIG. 1-6, four lasers 21 are arranged on the bearer 18. In further embodiments of the invention however, more or fewer lasers are also provided.

The retaining device 9 serves to retain a solar module 23 consisting of plate glass. The solar module 23 is thus retained by the retainer means 13 underneath the retaining device 9. The retainer means 13 are in the form of so-called Bernoulli grippers. The Bernoulli grippers generate a negative pressure by means of an air stream blown on to a surface of the solar module 23, with which the solar module 23 onto which the air is blown is sucked towards the Bernoulli grippers. Due to the large number of the retainer means 13 constructed as Bernoulli grippers positioned on the retaining device 9, large objects, such as for example a solar module 23, can be retained. Due to the escaping air stream, which is blown on to the surface of the solar module 23 by the Bernoulli grippers, no contact takes place between solar module 23 and retainer means 13. Between the solar module 23 and the Bernoulli grippers there remains a small gap, through which the escaping air flows out either laterally or radially.

The solar module 23 comprises a coating on the upper side on to which air is blown, which points in the direction of the retainer means 13. To perform the structuring of this coating, the lasers 21 are moved underneath the solar module 23 on the carriage 19 across the full extent of the solar module 23. The solar module is smaller than a plane defined by the mounting elements 6 and 7, which means the lasers 21 reach the entire area of the solar module 23. The lasers 21 burn a structuring into the coating from underneath the solar module, in the form of discontinuities, the coating being burnt off or vaporised. Due to the non-contacting retention of the solar module 23 therefore, the structuring process can also take place in the region of the retainer means 13 (Bernoulli grippers). Displacement of the solar module 23 and of the retainer means 13 is therefore eliminated. By means of the air stream, which is blown by the Bernoulli grippers on to the surface of the solar module 23, particles produced by the combustion of the coating are carried away. In addition, gases produced in the combustion are blown away. Not shown are one or more suction devices, which are arranged both above the retaining device 9 and to the side of it. A suction device receives the particles and gases blown away by the Bernoulli grippers.

Not shown in the Figures is a positioning aid, which holds the solar module in position laterally. By retaining the solar module 23 in a non-contact manner using the retaining device 9 the solar module 23 can be displaced by external effects. For the structuring of the coating of the solar module 23 however, it is important that the solar module 23 is held in position. The positioning aid can therefore consist of a rod or any other means of positioning, which is brought towards the solar module 23 from the side. It is provided that the solar module 23 is secured in every possible direction.

In another exemplary embodiment, not shown, the retaining device 9 can be rotated parallel to a plane of the solar module 23. Here it is sufficient for the solar module 23 to be turned by 90° either clockwise or anti-clockwise. The structuring of a solar module 23 is very complex, so that by the rotation of the retaining device 9 with the solar module 23 the machining time can be shortened.

The structuring with the lasers 21 requires an accurate guiding of the laser 21 underneath the solar module 23. In fact the burning off of the coating on the upper side of the solar module 23 takes place only in a focussing range of the laser beam. To avoid inaccuracies in the guiding of the laser it is provided, among other things, that the solar module 23 is retained at the height of the guide 14. At least however, it is provided that one rotational axis of the carriage 19 lies on the level of the solar module 23. By means of this arrangement the focussing range of the laser 21 remains stable in the region of the coating of the solar module 23.

While embodiments of the invention have been described herein, it should be understood that it has been presented by way of example only, and not limitation. Thus, the breadth and scope of the invention should not be limited by any of the described embodiments, but should instead be defined only in accordance with the following claims and their equivalents.

1-12. (canceled)

13. A device for structuring a solar module, comprising:
a retaining device which retains the solar module; and
at least one structuring tool for structuring at least one coating located on the solar module, the solar module being retained in a non-contact manner on an upper side facing away from the structuring tool, wherein the retaining device comprises one or more retainer means and the respective retainer means being constructed for sucking the solar module by means of suction air, wherein the retainer means is configured to generate a negative pressure on the upper side of the solar module by means of compressed air, and wherein the structuring tool comprises at least one carriage and at least one laser, wherein the respective laser is moveable in two dimensions underneath the respective solar module.

14. The device according to claim 13, wherein the structuring tool comprises multiple lasers, wherein said lasers are arranged underneath the retaining device and are retained in such a way that the lasers are moveable in two dimensions underneath the respective solar module.

15. The device according to claim 13, wherein the retainer means is configured to generate an additional air cushion, under which the solar module floats.

16. The device according to claim 13, wherein the structuring tool is arranged to be moveable underneath the retaining device.

17. The device according to claim 13, wherein the respective laser is moveable in a longitudinal and a transverse direction of the respective solar module.

18. The device according to claim 17, wherein the carriage comprises a bearer, on which the respective laser is arranged and which is displaceable on two parallel guides in the longitudinal direction of the respective solar module, the respective laser being displaceable on the bearer perpendicular to the longitudinal direction of the guides.

19. The device of claim 18, wherein on each free end the bearer comprises a chassis, which mates with one of the guides.

20. The device according to claim 18, wherein each guide is arranged in a plane with the solar module.

21. The device according to claim 13, wherein a free space is provided underneath a machining region of the structuring tool.

22. The device according to claim 13, wherein the retaining device is freely rotatable by 90° parallel to the plane of the solar module.

23. The device according to claim 13, wherein the retaining device serves to remove by suction any layer particles vaporised by the laser.

24. The device according to claim 13, wherein a positioning aid is arranged to the side of the solar module, which lies at least partly in the plane of the solar module, for positioning and/or fixing the solar module.

25. The device according to claim 13, wherein the negative pressure is generated according to a Bernoulli effect.

26. A device for structuring a solar module, comprising:
a retaining device including a Bernoulli gripper configured to retain an upper side of the solar module in a non-contact manner; and
a structuring tool located underneath the solar module and comprising a carriage and a laser, wherein the laser is moveable in two dimensions and is configured to burn discontinuities into a coating located on the upper side of the solar module facing away from the structuring tool.
